(19) United States
(12) Patent Application Publication
(10) Pub. No.: US 2012/0141924 A1
(43) Pub. Date: Jun. 7, 2012

(54) Multiresolution Mask Writing

(76) Inventor: Emile Y. Sahouria, Sunnyvale, CA (US)

(21) Appl. No.: 13/175,823

(22) Filed: Jul. 1, 2011

Related U.S. Application Data
(60) Provisional application No. 61/360,858, filed on Jul. 1, 2010.

(51) Int. Cl. G03F 1/76

(52) U.S. Cl. 430/5

(57) ABSTRACT

Mask writing techniques that employ multiple masking writing passes. A first writing pass is made to write a first shot pattern having a first resolution. A second writing pass is then made to write a second shot pattern having a second resolution finer than the first resolution, such that the second shot pattern substantially overlaps with the first shot pattern on the mask substrate.

### RELATED APPLICATIONS

This application claims priority under 35 U.S.C. §120 to U.S. patent application No. 61/360,858, entitled “Multiresolution Mask Writing,” filed on Jul. 1, 2010, and naming Emile Sahouria as inventor, which application is incorporated entirely herein by reference.

### FIELD OF THE INVENTION

The present invention is directed techniques for creating masks for use in photolithographic manufacturing processes. Various implementations of the invention may be particularly useful for reducing a number of shots to form a photolithograph mask by writing a mask image multiple times at different resolutions.

### BACKGROUND OF THE INVENTION

Microdevices, such as integrated microcircuits and microelectromechanical systems (MEMS), are used in a variety of products, from automobiles to microwaves to personal computers. Designing and fabricating microdevices typically involves many steps, known as a “design flow.” The particular steps of a design flow often are dependent upon the type of microcircuit, its complexity, the design team, and the microdevice fabricator or foundry that will manufacture the microcircuit. Typically, software and hardware “tools” verify the design at various stages of the design flow by running software simulators and/or hardware emulators, and errors in the design are corrected or the design is otherwise improved.

Several steps are common to most design flows for integrated microcircuits. Initially, the specification for a new circuit is transformed into a logical design, sometimes referred to as a register transfer level (RTL) description of the circuit. With this logical design, the circuit is described in terms of both the exchange of signals between hardware registers and the logical operations that are performed on those signals. The logical design typically employs a Hardware Design Language (HDL), such as the Very high speed integrated circuit Hardware Design Language (VHDL). The logic of the circuit is then analyzed, to confirm that it will accurately perform the functions desired for the circuit. This analysis is sometimes referred to as “functional verification.”

After the accuracy of the logical design is confirmed, it is converted into a device design by synthesis software. The device design, which is typically in the form of a schematic or netlist, describes the specific electronic devices (such as transistors, resistors, and capacitors) that will be used in the circuit, along with their interconnections. This device design generally corresponds to the level of representation displayed in conventional circuit diagrams. Preliminary timing estimates for portions of the circuit may be made at this stage, using an assumed characteristic speed for each device. In addition, the relationships between the electronic devices are analyzed, to confirm that the circuit described by the device design will correctly perform the desired functions. This analysis is sometimes referred to as “formal verification.”

Once the relationships between circuit devices have been established, the design is again transformed, this time into a physical design that describes specific geometric elements. This type of design often is referred to as a “layout” design. The geometric elements, which typically are polygons, define the shapes that will be created in various materials to manufacture the circuit. Typically, a designer will select groups of geometric elements representing circuit device components (e.g., contacts, gates, etc.) and place them in a design area. These groups of geometric elements may be custom designed, selected from a library of previously-created designs, or some combination of both. Lines are then routed between the geometric elements, which will form the wiring used to interconnect the electronic devices. Layout tools (often referred to as “place and route” tools), such as Mentor Graphics' IC Station or Cadence's Virtuoso, are commonly used for both of these tasks.

With a layout design, each physical layer of the circuit will have a corresponding layer representation in the design, and the geometric elements described in a layer representation will define the relative locations of the circuit device components that will make up a circuit device. Thus, the geometric elements in the representation of an implant layer will define the doped regions, while the geometric elements in the representation of a metal layer will define the locations in a metal layer where conductive wires will be formed to connect the circuit devices. In addition to integrated circuit microdevices, layout design data also is used to manufacture other types of microdevices, such as microelectromechanical systems (MEMS). Typically, a designer will perform a number of analyses on the layout design data. For example, with integrated circuits, the layout design may be analyzed to confirm that it accurately represents the circuit devices and their relationships as described in the device design. The layout design also may be analyzed to confirm that it complies with various design requirements, such as minimum spacings between geometric elements. Still further, the layout design may be modified to include the use of redundant geometric elements or the addition of corrective features to various geometric elements, to counteract limitations in the manufacturing process, etc.

After the layout design has been finalized, then it is converted into a format that can be employed by a mask or reticle writing tool to create a mask or reticle for use in a photolithographic manufacturing process. Masks and reticles are typically made using tools that expose a blank reticle to an electron or laser beam. Most mask writing tools are able to only “write” certain kinds of polygons, however, such as right triangles, rectangles or other trapezoids. Moreover, the sizes of the polygons are limited physically by the maximum beam aperture size available to the tool. Accordingly, larger geometric elements in the layout design, or geometric elements that are not basic right triangles, rectangles or trapezoids (which typically is a majority of the geometric elements in a layout design) must be “fractured” into the smaller, more basic polygons, sometimes called “shots,” that can be written by the mask or reticle writing tool.

Once the layout design has been fractured, then the fractured layout design data can be converted to a format compatible with the mask or reticle writing tool. Examples of such formats are MEBES, for raster scanning machines manufactured by ETEC, an Applied Materials Company, the “.MIC” format from Micronics AB in Sweden, and various vector scan formats for Nuflare, JEOL, and Hitachi machines, such as VSB12 or VSB12. The written masks or reticles can then be used in a photolithographic process to expose selected areas of a wafer in order to produce the desired integrated circuit devices on the wafer.

During a conventional mask writing process, a mask writer may make multiple passes of exposure over the mask substrate, with each pass writing the same pattern of shots. The reasons for using multiple mask writing passes are varied, and include controlling placement errors due to mechanical stage movement, reducing line edge roughness by limiting shot noise magnitude, and increasing the amount of energy deposited per area in the presence of various per-shot constraints. With a conventional mask writing process, however, the total write time is dependent upon the number of shots being written, and can be substantial. Accordingly, the industry is continuously trying to reduce the total write time for forming lithographic masks.

### BRIEF SUMMARY OF THE INVENTION

Aspects of the invention relate to mask writing techniques that employ multiple masking writing passes. According to various implementations of the invention, a first writing pass is made to write a first shot pattern having a first resolution. A second writing pass is then made to write a second shot pattern having a second resolution finer than the first resolution, such that the second shot pattern substantially overlaps with the first shot pattern on the mask substrate. With various implementations of the invention, the shot pattern with the coarser resolution can be formed from fewer shots than a corresponding conventional shot pattern, allowing it to be written more quickly than a corresponding conventional shot pattern. Moreover, the overlap of the first, coarse shot pattern with the second, finer shot pattern can be selected so that the first, coarse shot pattern combines with the second, finer shot pattern to form a desired shot pattern on the mask substrate. According to various implementations of the invention, the two patterns must be defined jointly with the use of a MPC tool.

### BRIEF DESCRIPTION OF THE DRAWINGS

FIGS. 1 and 2 illustrate a computing system that may be employed to implement a mask writing system according to various embodiments of the invention.

FIG. 3 illustrates the overlap of a course shot pattern and a fine shot pattern that may be provided according to various embodiments of the invention.

FIGS. 4A and 5A illustrate top-down views of mask edges from two passes for a larger maximum deviation and a smaller maximum deviation, respectively.

FIGS. 4B and 5B illustrate the image cross sections at the indicated cut lines in FIGS. 4A and 5A, respectively.

FIG. 6 illustrates a graph showing the results of overexposing a multiresolution test pattern on a mask writer.

FIG. 7 illustrates the mask data processing (MDP) flow that may be implemented for multiresolution mask writing according to various embodiments of the invention

### DETAILED DESCRIPTION OF THE INVENTION

### Exemplary Operating Environment

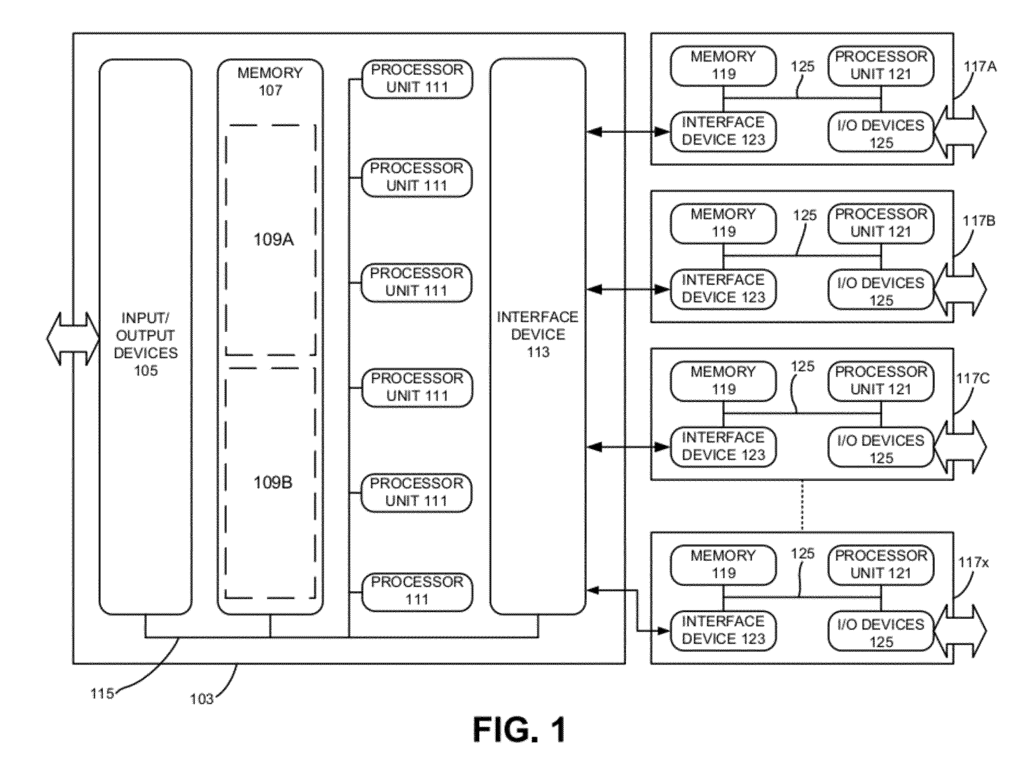

The execution of various electronic design automation processes according to embodiments of the invention may be implemented using computer-executable software instructions executed by one or more programmable computing devices. Because these embodiments of the invention may be implemented using software instructions, the components and operation of a generic programmable computer system on which various embodiments of the invention may be employed will first be described. Further, because of the complexity of some electronic design automation processes and the large size of many circuit designs, various electronic design automation tools are configured to operate on a computing system capable of simultaneously running multiple processing threads. The components and operation of a computer network having a host or master computer and one or more remote or servant computers therefore will be described with reference to FIG. 1. This operating environment is only one example of a suitable operating environment, however, and is not intended to suggest any limitation as to the scope of use or functionality of the invention.

In FIG. 1, the computer network 101 includes a master computer 103. In the illustrated example, the master computer 103 is a multi-processor computer that includes a plurality of input and output devices 105 and a memory 107. The input and output devices 105 may include any device for receiving input data from or providing output data to a user. The input devices may include, for example, a keyboard, microphone, scanner or pointing device for receiving input from a user. The output devices may then include a display monitor, speaker, printer or tactile feedback device. These devices and their connections are well known in the art, and thus will not be discussed at length here.

The memory 107 may similarly be implemented using any combination of computer readable media that can be accessed by the master computer 103. The computer readable media may include, for example, microcircuit memory devices such as read-write memory (RAM), read-only memory (ROM), electronically erasable and programmable read-only memory (EEPROM) or flash memory microcircuit devices, CD-ROM disks, digital video disks (DVD), or other optical storage devices. The computer readable media may also include magnetic cassettes, magnetic tapes, magnetic disks or other magnetic storage devices, punched media, holographic storage devices, or any other medium that can be used to store desired information.

As will be discussed in detail below, the master computer 103 runs a software application for performing one or more operations according to various examples of the invention. Accordingly, the memory 107 stores software instructions 109A that, when executed, will implement a software application for performing one or more operations. The memory 107 also stores data 109B to be used with the software application. In the illustrated embodiment, the data 109B contains process data that the software application uses to perform the operations, at least some of which may be parallel.

The master computer 103 also includes a plurality of processor units 111 and an interface device 113. The processor units 111 may be any type of processor device that can be programmed to execute the software instructions 109A, but will conventionally be a microprocessor device. For example, one or more of the processor units 111 may be a commercially generic programmable microprocessor, such as Intel® Pentium® or Xeon™ microprocessors, Advanced Micro Devices Athlon™ microprocessors or Motorola 68K/Coldfire® microprocessors. Alternately or additionally, one or more of the processor units 111 may be a custom-manufactured processor, such as a microprocessor designed to optimally perform specific types of mathematical operations. The interface device 113, the processor units 111, the memory 107 and the input/output devices 105 are connected together by a bus 115.

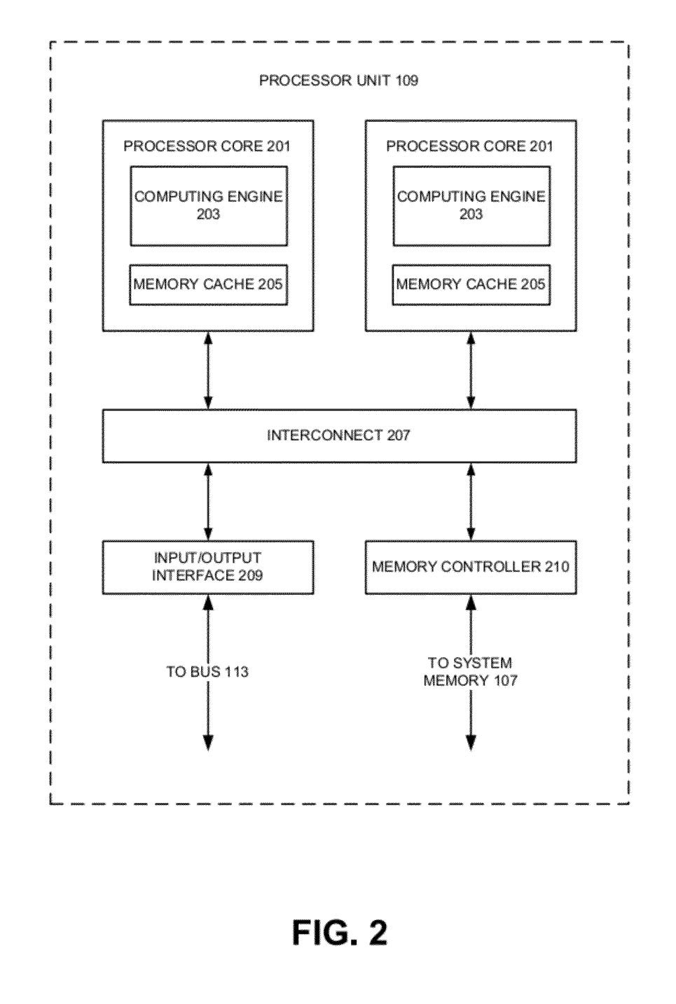

With some implementations of the invention, the master computing device 103 may employ one or more processing units 111 having more than one processor core. Accordingly, FIG. 2 illustrates an example of a multi-core processor unit 111 that may be employed with various embodiments of the invention. As seen in this figure, the processor unit 111 includes a plurality of processor cores 201. Each processor core 201 includes a computing engine 203 and a memory cache 205. As known to those of ordinary skill in the art, a computing engine contains logic devices for performing various computing functions, such as fetching software instructions and then performing the actions specified in the fetched instructions. These actions may include, for example, adding, subtracting, multiplying, and comparing numbers, performing logical operations such as AND, OR, NOR and XOR, and retrieving data. Each computing engine 203 may then use its corresponding memory cache 205 to quickly store and retrieve data and/or instructions for execution.

Each processor core 201 is connected to an interconnect 207. The particular construction of the interconnect 207 may vary depending upon the architecture of the processor unit 201. With some processor cores 201, such as the Cell microprocessor created by Sony Corporation, Toshiba Corporation and IBM Corporation, the interconnect 207 may be implemented as an interconnect bus. With other processor units 201, however, such as the Opteron™ and Athlon™ dual-core processors available from Advanced Micro Devices of Sunnyvale, Calif., the interconnect 207 may be implemented as a system request interface device. In any case, the processor cores 201 communicate through the interconnect 207 with an input/output interface 209 and a memory controller 211. The input/output interface 209 provides a communication interface between the processor unit 201 and the bus 115. Similarly, the memory controller 211 controls the exchange of information between the processor unit 201 and the system memory 107. With some implementations of the invention, the processor units 201 may include additional components, such as a high-level cache memory accessible shared by the processor cores 201.

While FIG. 2 shows one illustration of a processor unit 201 that may be employed by some embodiments of the invention, it should be appreciated that this illustration is representative only, and is not intended to be limiting. For example, some embodiments of the invention may employ a master computer 103 with one or more Cell processors. The Cell processor employs multiple input/output interfaces 209 and multiple memory controllers 211. Also, the Cell processor has nine different processor cores 201 of different types. More particularly, it has six or more synergistic processor elements (SPEs) and a power processor element (PPE). Each synergistic processor element has a vector-type computing engine 203 with 428×428 bit registers, four single-precision floating point computational units, four integer computational units, and a 556 KB local store memory that stores both instructions and data. The power processor element then controls that tasks performed by the synergistic processor elements. Because of its configuration, the Cell processor can perform some mathematical operations, such as the calculation of fast Fourier transforms (FFTs), at substantially higher speeds than many conventional processors.

It also should be appreciated that, with some implementations, a multi-core processor unit 111 can be used in lieu of multiple, separate processor units 111.

For example, rather than employing six separate processor units 111, an alternate implementation of the invention may employ a single processor unit 111 having six cores, two multi-core processor units each having three cores, a multi-core processor unit 111 with four cores together with two separate single-core processor units 111, etc.

Returning now to FIG. 1, the interface device 113 allows the master computer 103 to communicate with the servant computers 117A, 117B, 117C . . . 117x through a communication interface. The communication interface may be any suitable type of interface including, for example, a conventional wired network connection or an optically transmissive wired network connection. The communication interface may also be a wireless connection, such as a wireless optical connection, a radio frequency connection, an infrared connection, or even an acoustic connection. The interface device 113 translates data and control signals from the master computer 103 and each of the servant computers 117 into network messages according to one or more communication protocols, such as the transmission control protocol (TCP), the user datagram protocol (UDP), and the Internet protocol (IP). These and other conventional communication protocols are well known in the art, and thus will not be discussed here in more detail.

Each servant computer 117 may include a memory 119, a processor unit 121, an interface device 123, and, optionally, one more input/output devices 125 connected together by a system bus 127. As with the master computer 103, the optional input/output devices 125 for the servant computers 117 may include any conventional input or output devices, such as keyboards, pointing devices, microphones, display monitors, speakers, and printers. Similarly, the processor units 121 may be any type of conventional or custom-manufactured programmable processor device. For example, one or more of the processor units 121 may be commercially generic programmable microprocessors, such as Intel® Pentium® or Xeon™ microprocessors, Advanced Micro Devices Athlon™ microprocessors or Motorola 68K/Coldfire® microprocessors. Alternately, one or more of the processor units 121 may be custom-manufactured processors, such as microprocessors designed to optimally perform specific types of mathematical operations. Still further, one or more of the processor units 121 may have more than one core, as described with reference to FIG. 2 above. For example, with some implementations of the invention, one or more of the processor units 121 may be a Cell processor. The memory 119 then may be implemented using any combination of the computer readable media discussed above. Like the interface device 113, the interface devices 123 allow the servant computers 117 to communicate with the master computer 103 over the communication interface.

In the illustrated example, the master computer 103 is a multi-processor unit computer with multiple processor units 111, while each servant computer 117 has a single processor unit 121. It should be noted, however, that alternate implementations of the invention may employ a master computer having single processor unit 111. Further, one or more of the servant computers 117 may have multiple processor units 121, depending upon their intended use, as previously discussed. Also, while only a single interface device 113 or 123 is illustrated for both the master computer 103 and the servant computers, it should be noted that, with alternate embodiments of the invention, either the computer 103, one or more of the servant computers 117, or some combination of both may use two or more different interface devices 113 or 123 for communicating over multiple communication interfaces.

With various examples of the invention, the master computer 103 may be connected to one or more external data storage devices. These external data storage devices may be implemented using any combination of computer readable media that can be accessed by the master computer 103. The computer readable media may include, for example, microcircuit memory devices such as read-write memory (RAM), read-only memory (ROM), electronically erasable and programmable read-only memory (EEPROM) or flash memory microcircuit devices, CD-ROM disks, digital video disks (DVD), or other optical storage devices. The computer readable media may also include magnetic cassettes, magnetic tapes, magnetic disks or other magnetic storage devices, punched media, holographic storage devices, or any other medium that can be used to store desired information. According to some implementations of the invention, one or more of the servant computers 117 may alternately or additionally be connected to one or more external data storage devices. Typically, these external data storage devices will include data storage devices that also are connected to the master computer 103, but they also may be different from any data storage devices accessible by the master computer 103.

It also should be appreciated that the description of the computer network illustrated in FIG. 1 and FIG. 2 is provided as an example only, and it not intended to suggest any limitation as to the scope of use or functionality of alternate embodiments of the invention.

### Overview Of Multiresolution Mask Writing

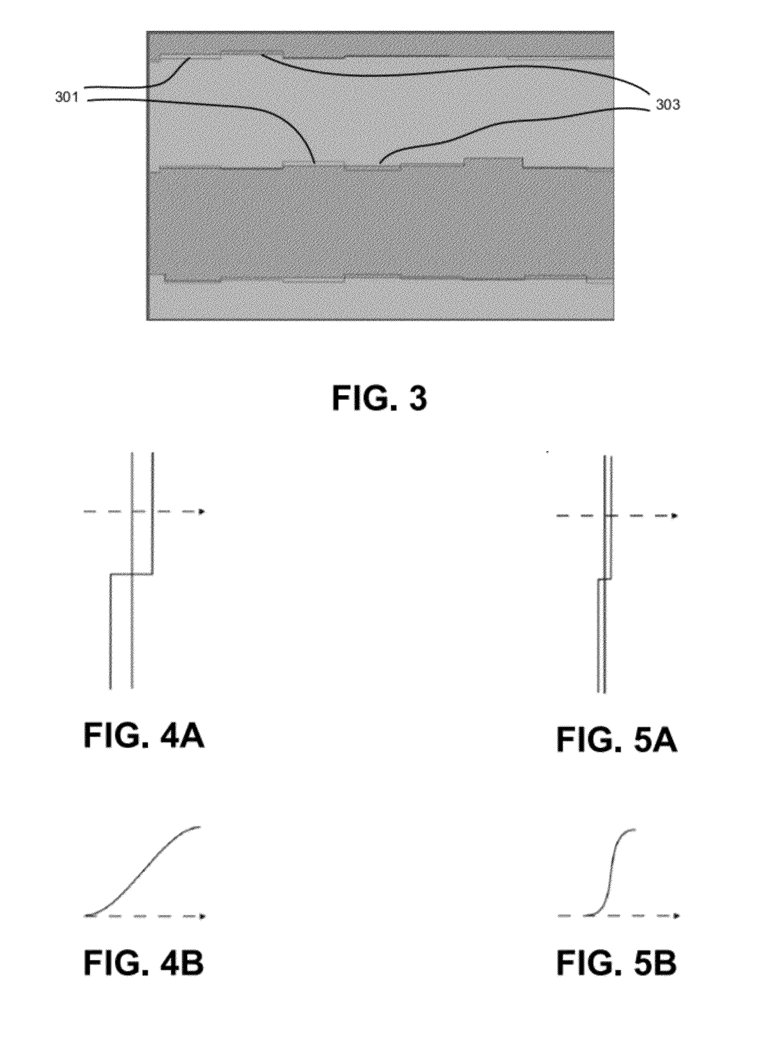

With mask writing techniques according to various implementations of the invention, a first writing pass is made to write a first shot pattern having a first resolution onto a mask substrate. A second writing pass is then made to write a second shot pattern having a second resolution finer than the first resolution, such that the second shot pattern substantially overlaps with the first shot pattern on the mask substrate. By relaxing the requirement of identical geometry in each pass, various embodiments of the invention provide a degree of freedom useful for shot count control. Specifically, as shown in FIG. 3, a “coarse” exposure pattern 301 may be used to deliver a dose of energy in one pass that approximates the desired intensity profile for forming a target mask, and a second “detailed” exposure pattern 303 may deliver another dose that “refines” the total intensity distribution to match the target. While the detailed pattern will have geometric complexity equivalent to the target pattern, the coarse layer will have substantially lower complexity. As a result, multiresolution mask writing according to various implementations of the invention can reduce the shot count compared to conventional multi-pass writing.

Implementations of the various embodiments of the invention method may follow from assessing the constraints on multi-pass writing and determining which constraints may be relaxed to reduce the shot count without degrading the resultant quality of the image target formed by the combined patterns. The image target should be realized at the best process condition. In addition, it should have sufficient, even maximal, exposure latitude, and energy should ideally be equally divided between the two passes at relatively local length scales. The first constraint does not intrinsically require identical shot exposures between passes. The third requirement suggests that, within some tolerance, the exposure patterns of the differently-resolved shot patterns should be close to each other. The second constraint also implies similarity between the differently-resolved shot patterns.

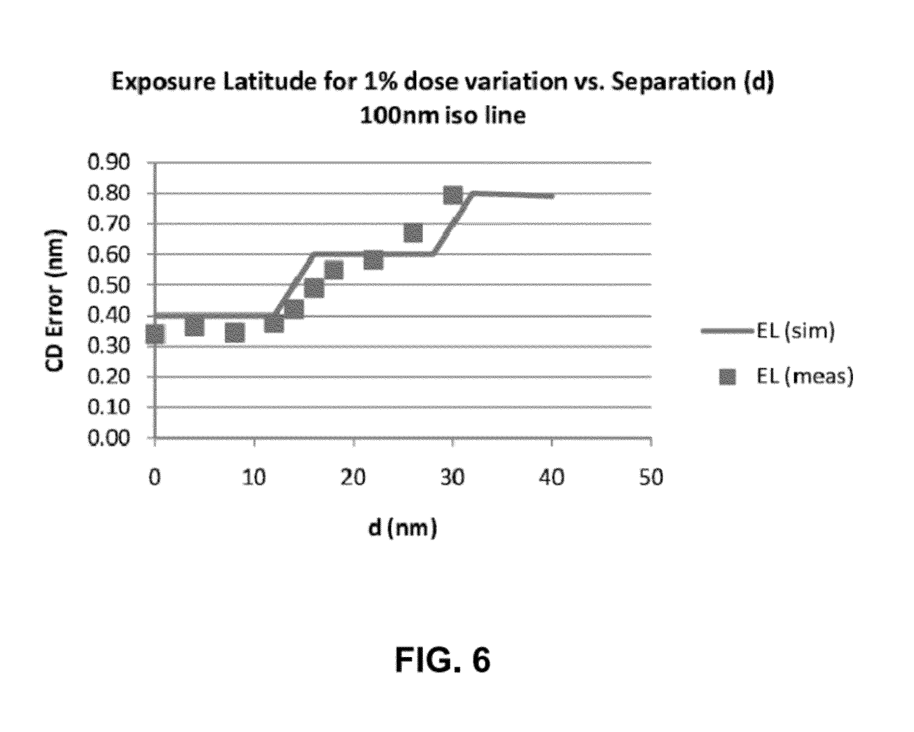

When the exposure patterns in mask writer passes are the same, and in the absence of any noise or machine errors, the image formed on the mask substrate is the same as that of a single pass with a dose equal to the sum of the doses of the multiple passes. However, when the exposure patterns are different, the image slope may degrade even if the image placement is correct. The slope degradation makes the image placement more sensitive to dose errors. This sensitivity increase is directly related to the distance between the edges of the two exposure patterns, as illustrated by the difference between the sensitivity shown in FIG. 4B (corresponding to the edge distance illustrated in FIG. 4A) and the sensitivity shown in FIG. 5B (corresponding to the edge distance illustrated in FIG. 5A), as dictated by mask writer physics. For a small maximum separation, the sensitivity increase is negligible. The theoretical insensitivity has been validated by intentionally overexposing a multiresolution test pattern on a mask writer, as illustrated in the graph of FIG. 6. This property defines the coarse/fine design problem: minimize the number of total shots while constraining the maximum edge separation between exposure layers. With various implementations of the invention, this may be accomplished using a conventional Mask Process Correction (MPC) tool.

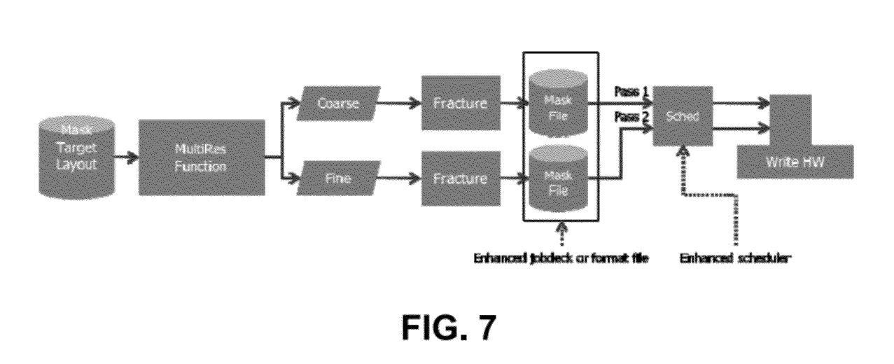

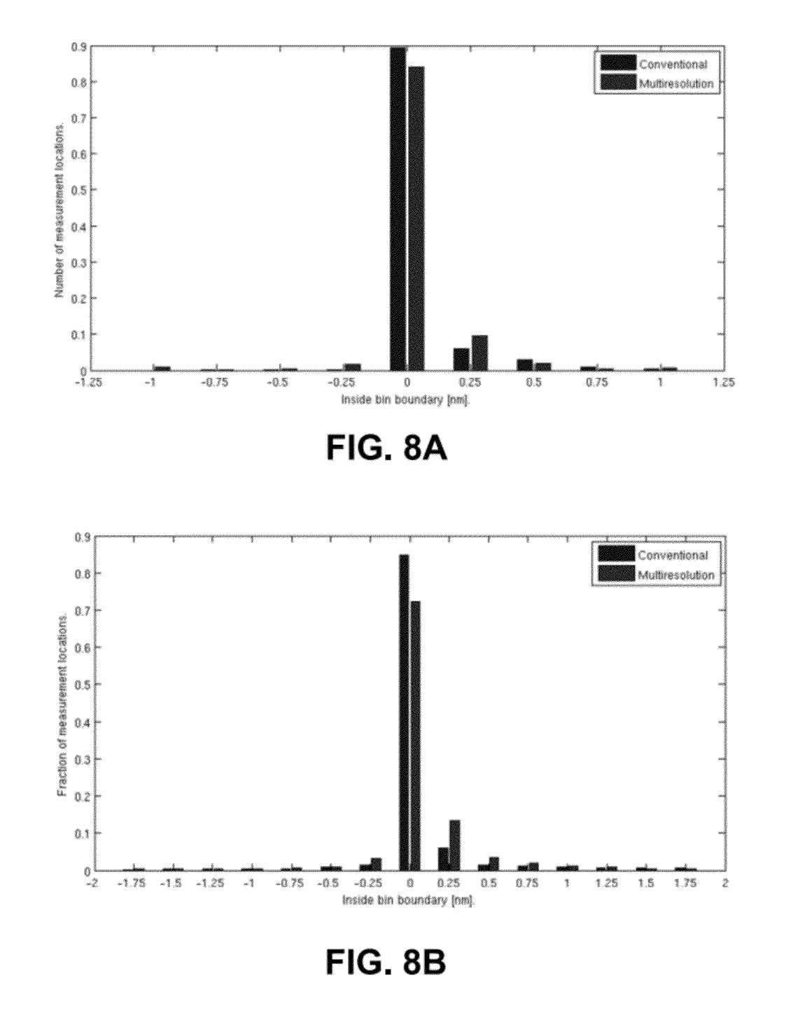

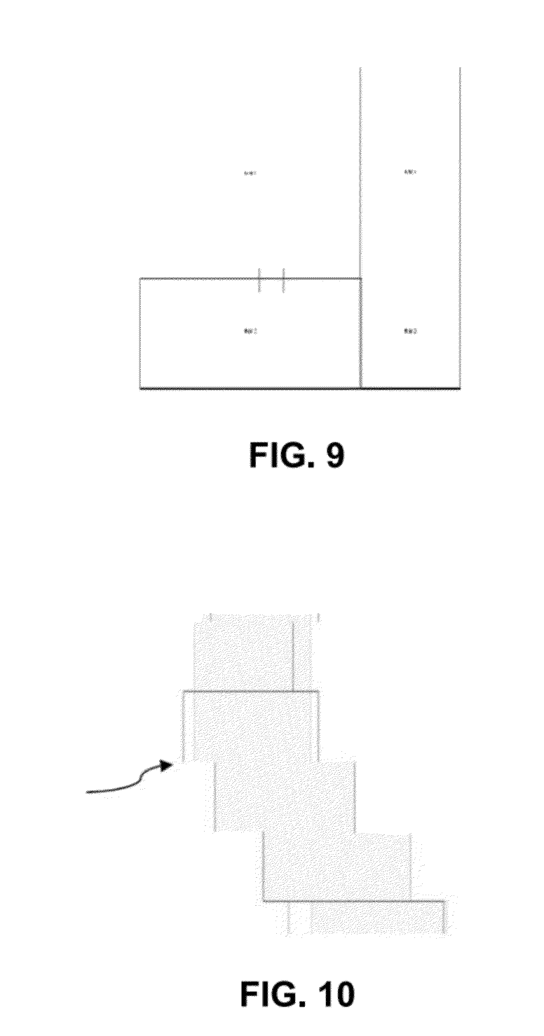

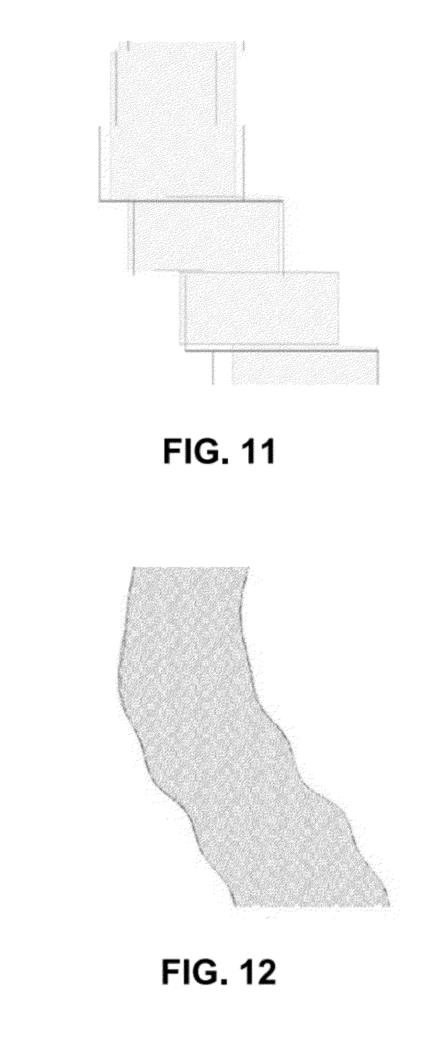

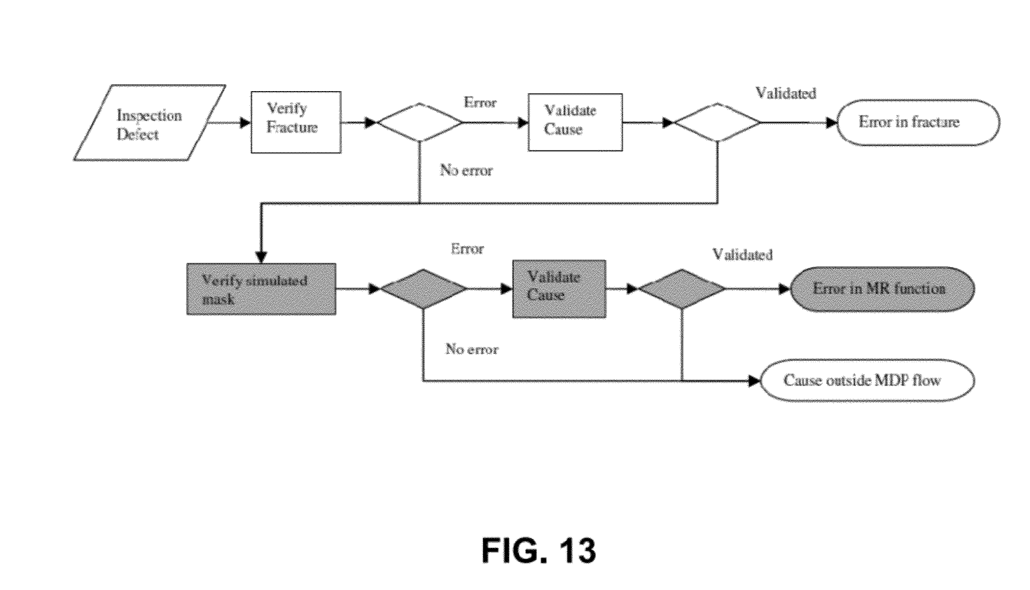

Mask process correction for the standard multi-pass scheme simply produces one exposure pattern that is used in all passes. An e-beam and/or etch model is used to simulate the mask image; then mask layout edges are moved to correct for distortions from a desired target shape. In multi-resolution writing according to various embodiments of the invention, two exposure layers are used: the detail and coarse exposure patterns. The two layers are generated jointly such that the image predicted by the MPC model matches the target. The generating algorithm constrains the maximum distance between edges on different layers. FIG. 7 illustrates the mask data processing (MDP) flow that may be implemented for multiresolution mask writing according to various embodiments of the invention. As illustrated in FIGS. 4A-5B, for small values of the distance between pass edges that print the same target image point, error due to process variation is essentially constant. Thus, variation of the patterns on the two passes is permissible within this separation interval. It should be appreciated that, with some embodiments of the invention, the illustrated multiresolution processing function and the fracturing functions can be performed by a conventional programmable computer, such as the computer illustrated in FIGS. 1 and 2.

It should be appreciated that various embodiments of the invention may employ more than two passes. For example, some implementations of the invention, may have a four-pass scheme, with two identical detail layers and two identical coarse layers (e.g., just repeating the results for the two-pass case), two different detail layers and two identical coarse layers (all layers are generated jointly), etc. Of course, any number of combinations of coarse and fine patterns in multiple patterns can be employed according to various embodiments of the invention.

Various embodiments of the invention may employ the data flow in FIG. 7. The MPC function may corrects for short and medium range effects using, for example the techniques described in the article “Model Based Mask Process Correction And Verification For Advanced Process Nodes” by Lin et al., Proc. SPIE 7274 (2009), which is incorporated entirely herein by reference. With some implementations of the invention, the MPC function may alternately or additionally provide a linear Gaussian model for electron forward scattering and an empirical model to represent resist and etch effects as described in the article “Correction For Etch Proximity: New Models And Applications,” Proc. SPIE 4346 (2001), which is incorporated entirely herein by reference. Electron backscattering and other long range effects may be treated, but are typically corrected by the on-writer proximity effect correction (PEC) module. This separation of corrections at different scales is not a fundamental requirement but may be maintained nonetheless according to various embodiments of the invention to minimize deviation from proven MDP processes.

An example of shot count reduction according to various embodiments of the invention was measured for a number of layout samples. These are tabulated in Table 1. The total savings vs. multi-pass writing vary between 18 and 31%.

TABLE 1

| Layout description. | Shot count savings. |
|---|---|
| 32 nm metal 1 layer. | 18% |
| 22 nm “SMO” contact layer. | 24% |
| 45 nm metal 1 layer. | 31% |

Edge placement uniformity and shot count reduction were compared between the two methods via software simulation. The control MDP process consisted of standard MPC and fracture. The MDP process according to various embodiments of the invention consisted of the new multiresolution function and two fractures, one for each resulting layer. Two-pass writing was used; the shot count for the control method is twice the count of the shots in fracture result, while the count for the method according to various embodiments of the invention is the sum of the counts for the coarse and detail fracture results. The experimental parameters are listed in Table 2.

TABLE 2

| Parameter | Value |
|---|---|
| Layout description. | 32 nm metal 1 layout sample. |
| Maximum inter-pass distance. | 15 nm |
| E-beam model. | Single Gaussian. Sigma = 25 nm. |
| Etch model. | VEB. One Gaussian, two visible |
| | kernels. Maximum kernel |
| | radius = 783 nm. |
| Pass count. | 2 |
| Multi-pass MPC iteration count. | 4 |
| Multiresolulion MPC function. | Experimental. |
| Fracture “small_value” parameter. | 50 nm |
| Fracture “cd” parameter. | Automatic setting. |
| Process window corner overdose. | 0.5%. |

Edge placement errors were measured using an MPC verification function. Measurements were made both at best dose and at 0.5% uniform overexposure. The simulation at best dose showed no significant differences between the two methods, indicating that the multiresolution function operated as expected. At 0.5% overdose, the histogram of edge placement errors shifted to the right for both methods, but more strongly for the experimental method, as illustrated in FIG. 8A. The relative shift was expected as the slope of the multiresolution image is slightly less than the multi-pass image. However, the degradation was very small and likely would result in acceptable mask yield. Total shot count over both passes for this layout sample was 18% less for the multiresolution method vs. the multi-pass method.

FIG. 8B shows the results of a simulation in which both exposure dose and shot placement are varied. The same layout sample and parameters were used; in particular all shots are exposed with 0.5% overdose. In addition, shot location in each pass was modified by adding independent, identically distributed normal random variables to each of the x- and y-coordinates of each shot in the fracture result for each pass. The standard deviation of the normal distribution was 0.1 nm. Again, at these process conditions the most significant changes to the edge placement error histogram occur at the center bins.

As will be appreciated by those of ordinary skill in the art, a primary reason for multi-pass writing with conventional masking writing techniques is to reduce mechanically induced image errors. These errors occur when adjacent shots in an exposure pattern are exposed from different mechanical states of the writer. For instance, the shots may be exposed from different locations of a stepping or shifting stage. The generic solution is to produce different stage movement patterns, one for each pass of the writing. The boundaries between stage step locations in one pass are designed such that they are far from the boundaries in the other passes. The particular “stage position schedule” for a pass determines which shots are exposed for each stage position. The effect of a relative error between adjacent stage positions in one pass is reduced because the corresponding exposure energy at that location is divided over several passes, only one of which suffers the mechanically induced error.

In conventional multi-pass writing, the union of exposure shots over all stage positions is identical for every pass. Near mechanically induced pattern boundaries, image averaging will be done by the same shot pattern. With various embodiments of the invention, averaging of the slightly different shot patterns in multiresolution writing can achieve the same performance. The effectiveness of image averaging in the presence of field placement error was simulated for both multi-pass and multiresolution writing. The results, shown in FIGS. 9-12, illustrate the effect on the image at the boundary to be indistinguishable between the two methods.

More particularly FIG. 9 an examples of a small mask layout. The highlighted field is to be placed with an error in one writing pass, while the small box marks the region shown in the other parts of the figure. FIG. 10 illustrates the corresponding multiresolution shot patterns for the case where there is no error, and the arrow marks the field soft boundary. FIG. 11 illustrates the corresponding multiresolution shots in which the lower left field of the coarse writing pass was placed with a 0.2 degree counter clockwise rotation. The same error was introduced into one of the writing passes of the multi-pass method for use as the baseline. Lastly, FIG. 12 illustrates the simulated images for both writing methods in the presence of the field placement error.

If, however, future assessment or experience reveals unacceptable quality in the field boundary areas, various embodiments of the invention can be modified to change the multiresolution function to generate identical shot patterns for the two passes in those areas. Since the field boundaries are such a small fraction of the mask area the shot count savings will be largely the same.

In order to properly schedule the sequence of mechanical states for each pass of the mask writer, an explicit identification of the data for each pass in a multiresolution write should be employed. This differs from conventional multi-pass writing in which the given mask shot pattern is duplicated once per pass and each copy is scheduled according to its pass index. With various embodiments of the invention, this straightforward enhancement may be made to the jobdeck or formatted file syntax. Mask writer features that depend on the exposed shot pattern, such as PEC, must also be made aware of the explicit definition of data in each pass.

The proximity effect correction module of a mask writer should support different data between passes. In the worst case, this might require a new PEC algorithm. However, the similarity between the shapes in the passes of multiresolution writing may simplify the requirement for many implementations. More particularly, the small difference in deposited energy between the exposures for each pass may allow use of the same PEC solution as for conventional multi-pass writing for the same mask target pattern.

With various embodiments of the invention, any existing MPC step should be preserved without modification when attempting to adopt the new writing scheme. This can be accomplished directly if the existing MPC process has a precisely defined, published model for the e-beam image.

As will be appreciated by those of ordinary skill in the art, the input to the multiresolution part of the MDP process according to various embodiments of the invention is the post-MPC mask pattern, which is not the target mask pattern. A proper target for the multiresolution function according to various embodiments of the invention should therefore be defined. Since the multiresolution function addresses the short-range scattering effects of e-beam exposure, it is sufficient to simulate the post-MPC pattern with the short-range e-beam model from the MPC process. The resulting contour is then the target for the multiresolution function. The e-beam model is also provided to the MR function for its internal simulation needs. The output will be a pair of coarse and detail layers whose combined e-beam image would be the same as the given post-MPC pattern written via multi-pass operation.

The introduction of simulation-based multiresolution decomposition to a conventional MDP manufacturing flow may require an extension to the process of diagnosing errors found during mask inspection. FIG. 13 illustrates that simulation-based verification is required in some instances to distinguish between various potential sources of error.

### CONCLUSION

While the invention has been described with respect to specific examples including presently preferred modes of carrying out the invention, those skilled in the art will appreciate that there are numerous variations and permutations of the above described systems and techniques that fall within the spirit and scope of the invention as set forth in the appended claims. For example, while the mask writing passes that write the finer shot patterns have been described as being subsequent to the mask writing passes that write the coarser shot patterns, this order can be reversed. Further this order can be mixed for implementation of the invention employing three or more passes. Accordingly, while specific terminology has been employed above to refer to electronic design automation processes, it should be appreciated that various examples of the invention may be implemented using any desired combination of electronic design automation processes.

What is claimed is:

1. A method of writing a target image onto a mask substrate, comprising:
writing a first shot pattern onto a mask substrate, the first shot pattern having a first resolution; and
writing a second shot pattern onto a mask substrate, the second shot pattern having a second resolution finer than the first resolution, such that the second shot pattern substantially overlaps with the first shot pattern.
